(19) United States
(12) Patent Application Publication
(10) Pub. No.: US 2025/0158002 A1
(43) Pub. Date: May 15, 2025

(54) SEMICONDUCTOR PACKAGE

(71) Applicant: SAMSUNG ELECTRONICS CO., LTD., Suwon-si (KR)

(72) Inventors: AE-NEE JANG, Suwon-si (KR); Haseob SEONG, Suwon-si (KR)

(73) Assignee: SAMSUNG ELECTRONICS CO., LTD., Suwon-si (KR)

(21) Appl. No.: 18/939,655

(22) Filed: Nov. 7, 2024

(30) Foreign Application Priority Data
Nov. 9, 2023 (KR) 10-2023-0154615

(51) Int. Cl. H01L 25/18; H01L 23/00; H10B 80/00

(52) U.S. Cl. CPC H01L 25/18; H01L 24/05; H01L 24/08; H01L 24/16; H01L 2224/05647; H01L 2224/08059; H01L 2224/08145; H01L 2224/16145; H01L 2224/16227; H01L 2225/06541; H01L 2924/1431; H01L 2924/1436; H10B 80/00

(57) ABSTRACT

A semiconductor package may include a first semiconductor chip and a second semiconductor chip on the first semiconductor chip. The first semiconductor chip may include upper bonding pads in an upper portion thereof, and the second semiconductor chip may include lower bonding pads in a lower portion thereof. The first semiconductor chip and the second semiconductor chip may be connected to each other by the upper bonding pads and the lower bonding pads, which are in direct contact with each other. The upper bonding pads may include a first pad, a dummy pad, and a second pad, which are arranged to be adjacent to each other in a first direction, and the first pads and the second pads are configured to be applied with voltages of different levels from each other.

### CROSS-REFERENCE TO RELATED APPLICATION

This U.S. non-provisional patent application claims priority under 35 U.S.C. § 119 to Korean Patent Application No. 10-2023-0154615, filed on Nov. 9, 2023, in the Korean Intellectual Property Office, the entire contents of which are hereby incorporated by reference.

### BACKGROUND

### 1. Technical Field

Embodiments of the present disclosure relate to a semiconductor package, and in particular, to a semiconductor package including a plurality of stacked semiconductor chips.

### 2. Brief Description of Related Art

The rapid development of the electronics industry has led to an increasing demand for electronic devices with higher performance. In order to achieve higher performance, there is a growing demand for methods of arranging a plurality of semiconductor chips. In order to satisfy this demand, a semiconductor package technology has been proposed in which a plurality of vertically stacked semiconductor chips are connected using through-substrate vias (TSVs).

### SUMMARY

In a hybrid bonding process of bonding semiconductor chips in a vertical direction, a bonding void may occur on an adhesion surface of the semiconductor chip. An embodiment of the present disclosure provides a highly reliable semiconductor package that is configured to prevent a conductive material from moving through a bonding void by a potential difference between adjacent pads.

According to embodiments of the present disclosure, a semiconductor package may be provided and include: a first semiconductor chip; and a second semiconductor chip on the first semiconductor chip, wherein an upper portion of the first semiconductor chip includes upper bonding pads, wherein a lower portion of the second semiconductor chip includes lower bonding pads that are in direct contact with the upper bonding pads, wherein the first semiconductor chip and the second semiconductor chip are connected to each other by the upper bonding pads and the lower bonding pads, wherein the upper bonding pads include a first pad, a dummy pad, and a second pad, which are arranged in a first direction, wherein the first pad is adjacent to the dummy pad and the dummy pad is adjacent to the second pad, such that the dummy pad is in between the first pad and the second pad, and wherein the first pad and the second pad are configured to be applied with voltages of different levels from each other.

According to embodiments of the present disclosure, a semiconductor package may be provided and include: a first semiconductor chip; and a second semiconductor chip on the first semiconductor chip, wherein an upper portion of the first semiconductor chip includes upper bonding pads, wherein a lower portion of the second semiconductor chip includes lower bonding pads that are in direct contact with the upper bonding pads, wherein the first semiconductor chip and the second semiconductor chip are connected to each other by the upper bonding pads and the lower bonding pads, wherein the upper bonding pads include a first pad, a dummy pad, and a second pad, which are arranged in a first direction, wherein the first pad is adjacent to the dummy pad and the dummy pad is adjacent to the second pad, such that the dummy pad is in between the first pad and the second pad, and wherein the first pad is configured to be applied with a first power voltage, wherein the second pad is configured to be applied with one from among a second power voltage, a ground voltage, and a signal voltage, wherein a voltage level of the one from among the second power voltage, the ground voltage, and the signal voltage is greater than a voltage level of the first power voltage, and wherein the dummy pad is configured to be applied with a floating voltage.

According to embodiments of the present disclosure, a semiconductor package may be provided and include: a package substrate; an interposer on the package substrate; a logic chip on the interposer; and a plurality of chip stacks, which are spaced apart from each other with the logic chip interposed therebetween, wherein each of the plurality of chip stacks includes: a first semiconductor chip; and a second semiconductor chip on the first semiconductor chip. The first semiconductor chip includes an upper insulating layer at an upper level of the first semiconductor chip, uppermost metal lines in the upper insulating layer, and upper bonding pads on the uppermost metal lines. The second semiconductor chip includes a lower insulating layer at a lower level of the second semiconductor chip, and lower bonding pads in the lower insulating layer, the lower bonding pads being in direct contact with the upper bonding pads of the first semiconductor chip, wherein the first semiconductor chip and the second semiconductor are bonded to each other through the upper bonding pads and the lower bonding pads, wherein the upper bonding pads include a ground pad, a first power pad, a signal pad, and a first dummy pad, wherein the first dummy pad is between one from among the signal pad and the ground pad and the first power pad, and wherein the first dummy pad is disposed adjacent to the one from among the signal pad and the ground pad, and adjacent to the first power pad.

### BRIEF DESCRIPTION OF DRAWINGS

FIG. 1 is a sectional view illustrating a semiconductor package according to an embodiment of the present disclosure.

FIG. 2 is a plan view illustrating upper bonding pads and an uppermost metal line, which are disposed on a top surface of a second semiconductor chip.

FIG. 3A is a sectional view schematically illustrating a bonding portion of second semiconductor chips corresponding to a section of a line A-A′ of FIG. 2.

FIG. 3B is a sectional view schematically illustrating a bonding portion of second semiconductor chips corresponding to a section of a line B-B′ of FIG. 2.

FIG. 3C is a sectional view schematically illustrating a bonding portion of second semiconductor chips corresponding to a section of a line C-C′ of FIG. 2.

FIG. 3D is a sectional view schematically illustrating a bonding portion of second semiconductor chips corresponding to a section of a line D-D′ of FIG. 2.

FIG. 3E is a sectional view schematically illustrating a bonding portion of second semiconductor chips corresponding to a section of a line E-E′ of FIG. 2.

FIG. 4 is a sectional view schematically illustrating a bonding portion of second semiconductor chips corresponding to a section of a line F-F′ of FIG. 2.

FIG. 5 is a sectional view schematically illustrating a bonding portion of second semiconductor chips according to an embodiment of the present disclosure.

FIG. 6 is a plan view illustrating a bonding void on the top plan view of FIG. 2.

FIG. 7A is a sectional view schematically illustrating a bonding portion of second semiconductor chips corresponding to a section of a line A1-A1′ of FIG. 6.

FIG. 7B is a sectional view schematically illustrating a bonding portion of second semiconductor chips corresponding to a section of a line F1-F1′ of FIG. 6.

FIG. 8 is a plan view illustrating upper bonding pads, an uppermost metal line, and a bonding void, which are disposed on a top surface of a second semiconductor chip according to a comparative example.

FIG. 9 is a sectional view schematically illustrating a bonding portion of second semiconductor chips corresponding to a section of a line H-H′ of FIG. 8.

FIG. 10 is a plan view illustrating a semiconductor package according to an embodiment of the present disclosure.

FIG. 11 is a sectional view taken along a line I-I′ of FIG. 10.

### DETAILED DESCRIPTION

Non-limiting example embodiments of the present disclosure will now be described more fully with reference to the accompanying drawings, in which example embodiments are shown. Like reference numerals in the drawings denote like elements, and thus repeated description thereof may be omitted.

It will be understood that when an element or layer is referred to as being “on,” “connected to,” or “coupled to” another element or layer, it can be directly on, connected to, or coupled to the other element or layer or intervening elements or layers may be present. In contrast, when an element or layer is referred to as being “directly on,” “directly connected to,” or “directly coupled to” another element or layer, there are no intervening elements or layers present.

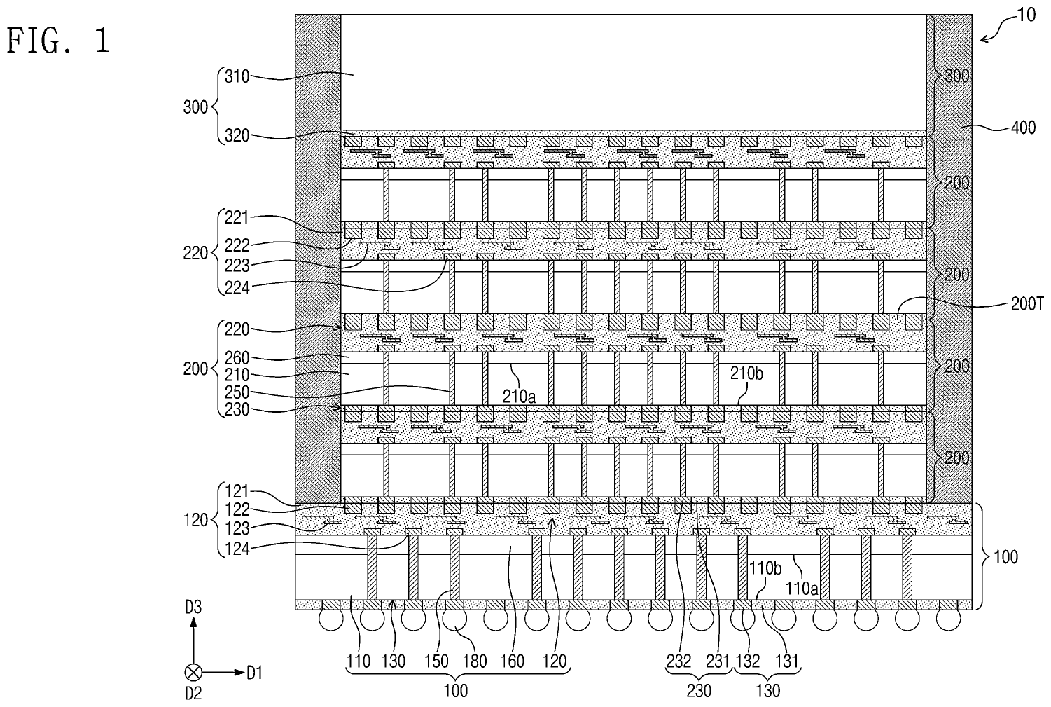

FIG. 1 is a sectional view illustrating a semiconductor package according to an embodiment of the present disclosure.

Referring to FIG. 1, a semiconductor package 10 may be a high bandwidth memory (HBM) device. In the present specification, the semiconductor package 10 may be called a chip stack. The semiconductor package 10 may include a first semiconductor chip 100, second semiconductor chips 200, a dummy plate 300, and a molding structure 400.

In the present specification, a direction, which is parallel to a top surface of the first semiconductor chip 100 or a top surface of the second semiconductor chips 200, may be defined as a first direction D1. A direction, which is parallel to the top surface of the first semiconductor chip 100 or the top surfaces of the second semiconductor chips 200 and is perpendicular to the first direction D1, may be defined as a second direction D2. A direction, which is perpendicular to the top surface of the first semiconductor chip 100 or the top surfaces of the second semiconductor chips 200, may be defined as a third direction D3.

In the present specification, an expression “a first element and a second element are adjacent to each other” may mean that an element equivalent to the first and second elements is not interposed between the first and second elements. As an example, an expression “a first semiconductor chip and a second semiconductor chip are adjacent to each other” may mean that another semiconductor chip (e.g., a third semiconductor chip) is not interposed between the first and second semiconductor chips. As another example, an expression “a first pad and a second pad are adjacent to each other” may mean that another pad (e.g., a third pad) is not interposed between the first pad and the second pad.

The first semiconductor chip 100 may be disposed as a bottom portion of the semiconductor package 10. In the present specification, the first semiconductor chip 100 may be referred to as a logic die, a logic chip, a base die, a buffer chip, a buffer die, or a memory controller. The first semiconductor chip 100 may be configured as a logic chip that increases data transmission efficiency and reduces power consumption. The first semiconductor chip 100 may include a first semiconductor substrate 110, a first upper interconnection layer 120, a first lower interconnection layer 130, first penetration electrodes 150, a first circuit layer 160, and connection terminals 180.

The first semiconductor substrate 110 may be formed of or include a semiconductor material (e.g., silicon or germanium). The first semiconductor substrate 110 may include a first top surface 110a and a first bottom surface 110b, which are opposite to each other.

The first circuit layer 160 may be disposed on the first top surface 110a of the first semiconductor substrate 110. An integrated circuit (e.g., a transistor) may be disposed in the first circuit layer 160.

The first upper interconnection layer 120 may be disposed on the first circuit layer 160. The first upper interconnection layer 120 may include a first upper insulating layer 121, first upper bonding pads 122, first upper interconnection line patterns 123, and first landing pads 124. The first upper insulating layer 121 may be formed of or include at least one from among, for example, silicon oxide (SiO₂), silicon nitride (Si₃N₄), and silicon oxynitride (SiOₓN_{y}). The first upper insulating layer 121 may include a plurality of insulating layers. The first upper insulating layer 121 may cover side and top surfaces of the first upper interconnection line pattern 123 and may cover a side surface of the first upper bonding pad 122. A top surface of the first upper bonding pad 122 may be exposed from the first upper insulating layer 121.

The first lower interconnection layer 130 may include a first lower insulating layer 131, connection pads 132, and first connection lines. The first lower insulating layer 131 may be formed of or include at least one from among, for example, silicon oxide (SiO₂), silicon nitride (Si₃N₄), and silicon oxynitride (SiOₓN_{y}). In an embodiment, a plurality of connection pads 132 may be provided, and at least one of the connection pads 132 may be in contact with the first penetration electrodes 150. The remaining ones of the connection pads 132 may be electrically connected to the at least one of the connection pads 132 through a connection line. A surface of the connection pad 132 may be exposed from the first lower insulating layer 131. The connection terminal 180 may be disposed on the exposed surface of the connection pad 132. The connection terminal 180 may be one from among, for example, a solder ball, a solder bump, and a solder pillar.

The first penetration electrode 150 may be provided to penetrate the first semiconductor substrate 110. The first penetration electrode 150 may be formed of or include a conductive material (e.g., copper). A diffusion prevention pattern (e.g., tantalum nitride (TaN), tantalum (Ta), titanium nitride (TiN), and tungsten (W)) may be disposed between the first penetration electrode 150 and the first semiconductor substrate 110. An end portion of the first penetration electrode 150 may be directly connected to the first landing pad 124, and an opposite end portion of the first penetration electrode 150 may be directly connected to the connection pad 132.

The second semiconductor chips 200 may be stacked on the first semiconductor chip 100. Each of the second semiconductor chips 200 may be a memory chip. The second semiconductor chip 200 may be one from among dynamic random-access memory (DRAM), static random-access memory (SRAM), and NAND FLASH chips. For example, the second semiconductor chip 200 may be a DRAM chip. The second semiconductor chips 200 may include the same integrated circuit or may be of the same kind. In the present specification, the second semiconductor chip 200 may be called a “core die” or “core chip.”

The second semiconductor chip 200 may include a second semiconductor substrate 210, a second upper interconnection layer 220, a second lower interconnection layer 230, second penetration electrodes 250, and a second circuit layer 260.

The second semiconductor substrate 210 may be formed of or include a semiconductor material (e.g., silicon or germanium). The second semiconductor substrate 210 may include a second top surface 210a and a second bottom surface 210b, which are opposite to each other.

The second circuit layer 260 may be disposed on the second top surface 210a of the second semiconductor substrate 210. An integrated circuit (e.g., a transistor) may be disposed in the second circuit layer 260.

The second upper interconnection layer 220 may be disposed on the second circuit layer 260. The second upper interconnection layer 220 may include a second upper insulating layer 221, second upper bonding pads 222, a second upper interconnection line pattern 223, and second landing pads 224. The second upper insulating layer 221 may be formed of or include at least one from among, for example, silicon oxide (SiO₂), silicon nitride (Si₃N₄), and silicon oxynitride (SiOₓN_{y}). The second upper insulating layer 221 may include a plurality of insulating layers. The second upper interconnection line pattern 223 may include a plurality of interconnection lines and vias connected thereto. The second upper bonding pad 222 may be placed in an upper portion of the second upper interconnection layer 220. The second upper insulating layer 221 may cover side and top surfaces of the second upper interconnection line pattern 223 and may cover a side surface of the second upper bonding pad 222. A top surface of the second upper bonding pad 222 may be exposed from the second upper insulating layer 221.

The second lower interconnection layer 230 may be disposed on the second bottom surface 210b. The second lower interconnection layer 230 may include a second lower insulating layer 231, second lower bonding pads 232, and second connection lines. The second lower insulating layer 231 may be formed of or include at least one from among, for example, silicon oxide (SiO₂), silicon nitride (Si₃N₄), and silicon oxynitride (SiOₓN_{y}). The second lower bonding pad 232 may be provided in the second lower insulating layer 231. In an embodiment, a plurality of second lower bonding pads 232 may be provided, and at least one of them may be directly connected to the second penetration electrodes 250. The remaining ones of the second lower bonding pads 232 may be electrically connected to the at least one of the second lower bonding pads 232 through the second connection line.

The second penetration electrode 250 may be provided to penetrate the second semiconductor substrate 210. The second penetration electrode 250 may be formed of or include a conductive material (e.g., copper). A diffusion prevention pattern (e.g., tantalum nitride (TaN)) may be disposed between the second penetration electrode 250 and the second semiconductor substrate 210. An end portion of the second penetration electrode 250 may be directly connected to the second landing pad 224, and an opposite end portion of the second penetration electrode 250 may be directly connected to at least one of the second lower bonding pads 232.

The first semiconductor chip 100 and one of the second semiconductor chips 200, which are adjacent to each other in the third direction D3, may be connected to each other through bonding pads, which are in direct contact with each other. For example, the top surface of the first upper bonding pad 122 of a lower semiconductor chip (e.g., the first semiconductor chip 100) may be in direct contact with a bottom surface of the second lower bonding pad 232 of an upper semiconductor chip (e.g., the second semiconductor chip 200). A top surface of the first upper insulating layer 121 of the first semiconductor chip 100 may be in direct contact with a bottom surface of the second lower insulating layer 231 of the second semiconductor chip 200.

The second semiconductor chips 200, which are adjacent to each other in the third direction D3, may be connected to each other through bonding pads, which are in direct contact with each other. For example, the top surface of the second upper bonding pad 222 of a lower one of the second semiconductor chips 200 may be in contact with the bottom surface of the second lower bonding pad 232 of an upper one of the second semiconductor chips 200. A top surface of the second upper insulating layer 221 of the lower one of the second semiconductor chips 200 may be in direct contact with the bottom surface of the second lower insulating layer 231 of the upper one of the second semiconductor chips 200.

The dummy plate 300 may be disposed on the uppermost one of the second semiconductor chips 200. The dummy plate 300 may include a dummy substrate 310 and an adhesive insulating layer 320. The dummy substrate 310 may be formed of or include a semiconductor material (e.g., silicon or germanium). For example, the dummy substrate 310 may be a silicon wafer. The dummy substrate 310 may not include an electronic device (e.g., an integrated circuit), interconnection patterns, and penetration electrodes. The adhesive insulating layer 320 may be in contact with the second upper interconnection layer 220 of one of the second semiconductor chips 200 (e.g., an uppermost one of the second semiconductor chips 200). The adhesive insulating layer 320 may be formed of or include at least one from among silicon oxide (SiO₂), silicon nitride (Si₃N₄), and silicon oxynitride (SiOₓN_{y}).

The molding structure 400 may cover the top surface of the first semiconductor chip 100 and may cover side surfaces of the second semiconductor chips 200 and a side surface of the dummy plate 300. The molding structure 400 may include an insulating material (e.g., an epoxy molding compound (EMC)).

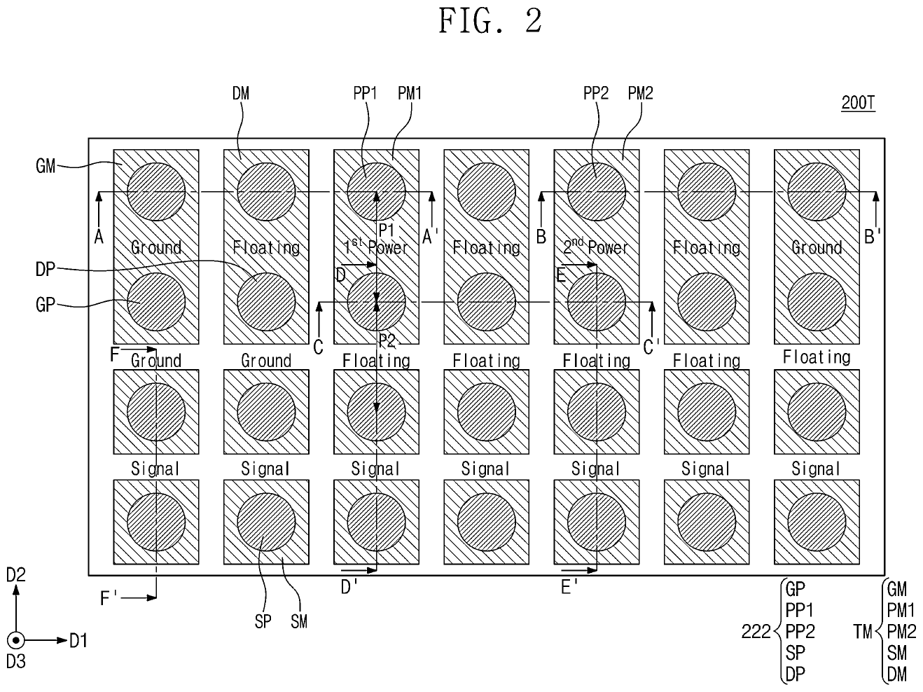

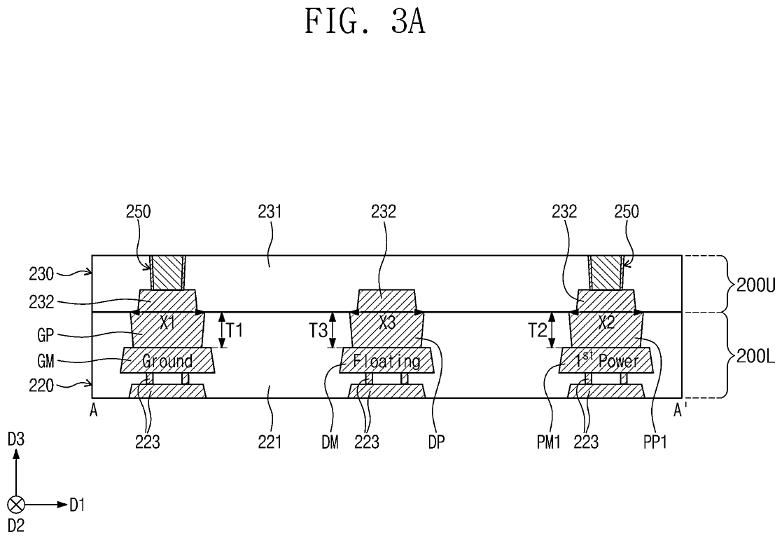

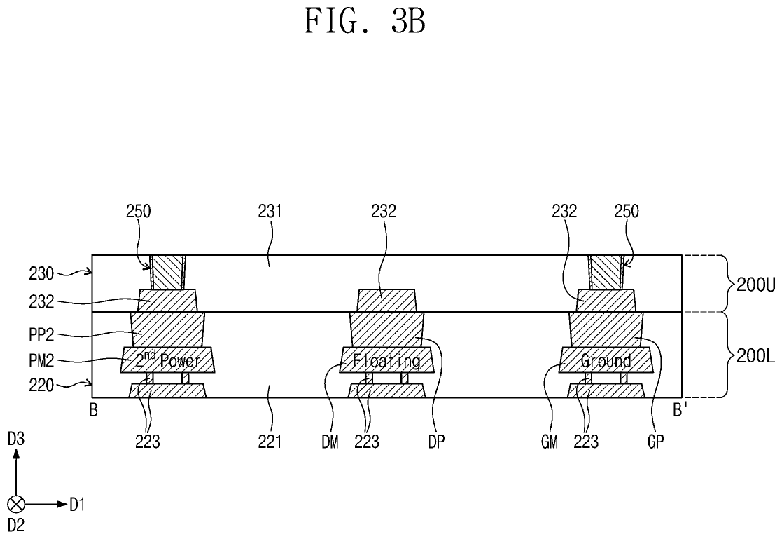

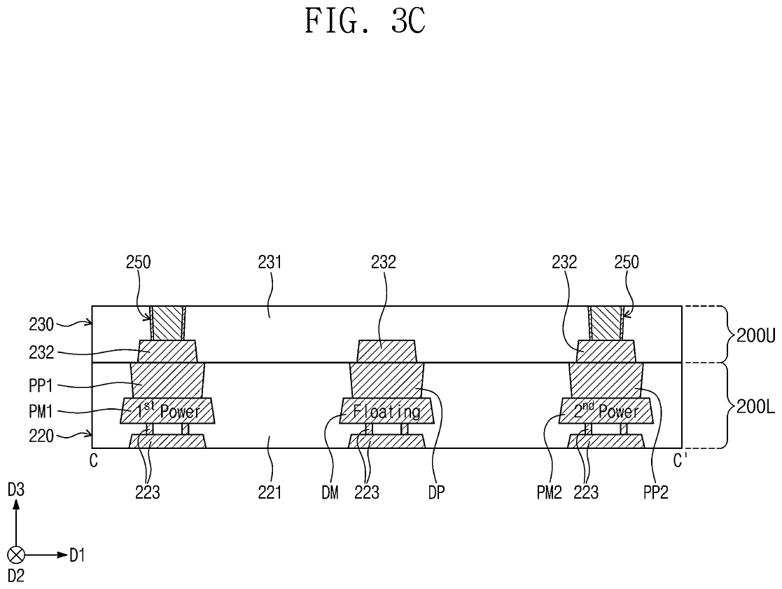

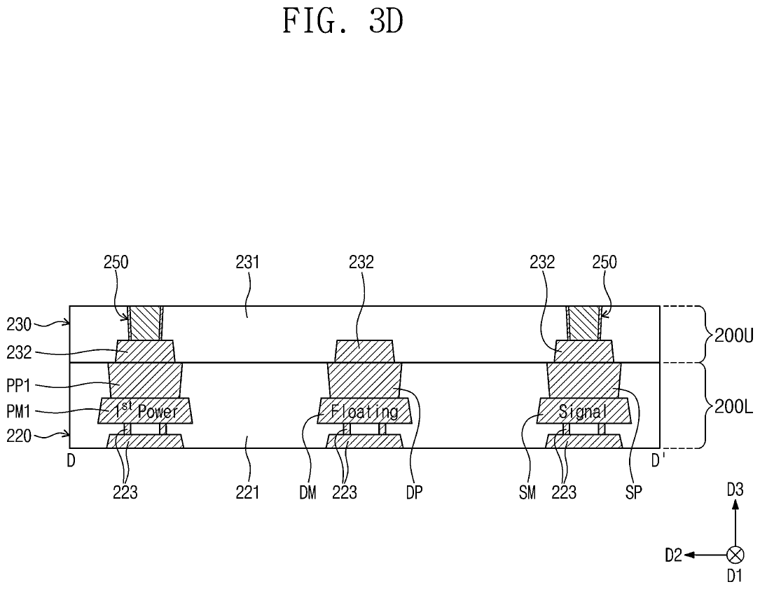

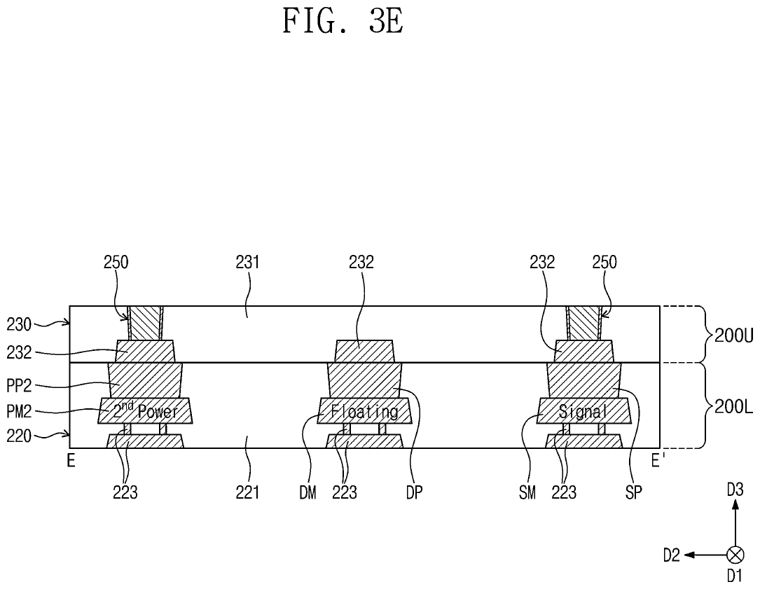

FIG. 2 is a plan view illustrating upper bonding pads and an uppermost metal line, which are disposed on a top surface of a second semiconductor chip. FIG. 3A is a sectional view schematically illustrating a bonding portion of second semiconductor chips corresponding to a section of a line A-A′ of FIG. 2. FIG. 3B is a sectional view schematically illustrating a bonding portion of second semiconductor chips corresponding to a section of a line B-B′ of FIG. 2. FIG. 3C is a sectional view schematically illustrating a bonding portion of second semiconductor chips corresponding to a section of a line C-C′ of FIG. 2. FIG. 3D is a sectional view schematically illustrating a bonding portion of second semiconductor chips corresponding to a section of a line D-D′ of FIG. 2. FIG. 3E is a sectional view schematically illustrating a bonding portion of second semiconductor chips corresponding to a section of a line E-E′ of FIG. 2.

Referring to FIGS. 1 and 2, the second upper interconnection line pattern 223 may include uppermost metal lines TM, which are placed at the uppermost level thereof. The uppermost metal lines TM may include, for example, aluminum. The uppermost metal lines TM may include at least one first power line PM1, at least one second power line PM2, at least one ground line GM, at least one signal line SM, and at least one dummy line DM.

One of an external voltage (VEXT) and a first data voltage (VDDQ) may be applied to the first power line PM1. For example, the external voltage (VEXT) may be applied to one of the first power lines PM1, and the first data voltage (VDDQ) may be applied to another one of the power lines PM1. The first data voltage (VDDQ) may mean a voltage of a data input/output buffer in a memory device (e.g., a DRAM device). A pumping voltage (VPPE) may be applied to the second power line PM2. The pumping voltage (VPPE) may be a high voltage, which is used to drive the second semiconductor chip 200. A ground voltage (VSS) or a second data voltage (VDDQL) may be applied to the ground line GM. The second data voltage (VDDQL) may be lower than the first data voltage (VDDQ). In an embodiment, the second data voltage (VDDQL) may be used for signal transmission through the second penetration electrodes 250. A voltage of an input/output signal may be applied to the signal line SM. The dummy line DM may be in a floating state or may be electrically disconnected from a node having a fixed supply voltage. For example, there may be no voltage applied to the dummy line DM; that is, a floating voltage may be applied to the dummy line DM.

A signal pad SP may be disposed on and in contact with the signal line SM in a one-to-one correspondence manner. In an embodiment, a plurality of signal pads SP may be placed on a plurality of signal lines SM in a one-to-one correspondence manner. A first power pad PP1 may be disposed on and in contact with the first power line PM1. In an embodiment, a plurality of first power pads PPI may be placed on one of the first power lines PM1 in a many-to-one correspondence manner or may be placed on the first power lines PM1 in a one-to-one correspondence manner. A second power pad PP2 may be disposed on and in contact with the second power line PM2. In an embodiment, a plurality of second power pads PP2 may be placed on one of the second power lines PM2 in a many-to-one correspondence manner or may be placed on the second power lines PM2 in a one-to-one correspondence manner. A ground pad GP may be disposed on and in contact with the ground line GM. In an embodiment, a plurality of ground pads GP may be placed on one of the ground lines GM in a many-to-one correspondence manner or may be placed on the ground lines GM in a one-to-one correspondence manner. A dummy pad DP may be disposed on and in contact with the dummy line DM. In an embodiment, a plurality of dummy pads DP may be placed on one of the dummy lines DM in a many-to-one correspondence manner or may be placed on the dummy lines DM in a one-to-one correspondence manner.

According to embodiments of the present disclosure, the second upper bonding pads 222 may include at least one of the ground pad GP, at least one of the first power pad PP1, at least one of the second power pad PP2, at least one of the signal pads SM, and least one of the dummy pad Dp.

A bonding portion of the second semiconductor chips 200, which are adjacent to each other in the third direction D3, will be described in more detail with reference to FIGS. 2 and 3A. A lower one of the second semiconductor chips 200, which are adjacent to each other in the third direction D3, will be referred to as a lower second semiconductor chip 200L, and an upper one of such second semiconductor chips will be referred to as an upper second semiconductor chip 200U.

The second upper interconnection layer 220 of the lower second semiconductor chip 200L may be in contact with the second lower interconnection layer 230 of the upper second semiconductor chip 200U. A diameter of the top surface of the second upper bonding pad 222 may be larger than a diameter of the bottom surface of the second lower bonding pad 232. In an embodiment, the diameter of the top surface of the second upper bonding pad 222 may be substantially equal to the diameter of the bottom surface of the second lower bonding pad 232. Alternatively, the diameter of the top surface of the second upper bonding pad 222 may be smaller than the diameter of the bottom surface of the second lower bonding pad 232.

The ground line GM and the first power line PM1 may be spaced apart from each other in the first direction D1, with the dummy line DM interposed therebetween. The ground line GM, the first power line PM1, and the dummy line DM may be extended in the second direction D2. The ground line GM and the first power line PM1 may be applied with different voltages from each other. A voltage level of a voltage applied to the first power line PM1 may be higher than a voltage level of a voltage applied to the ground line GM. For example, the first power line PM1 may be applied with a voltage of 1.1 V, and the ground line GM may be applied with a voltage of 0 V. No voltage may be applied to the dummy line DM. Since the ground pad GP is in contact with the ground line GM and is not in contact with other interconnection lines (e.g., the first power line PM1, the second power line PM2, the signal line SM, and the dummy line DM), the ground pad GP may be applied with the same voltage as the ground line GM. Since the first power pad PP1 is in contact with the first power line PM1 but is not in contact with other interconnection lines (e.g., the second power line PM2, the signal line SM, the dummy line DM, and the ground line GM), the same voltage as the first power line PM1 may be applied to the first power pad PP1. Since the dummy pad DP is in contact with the dummy line DM but is not in contact with other interconnection lines (e.g., the first power line PM1, the second power line PM2, the signal line SM, and the ground line GM), there may be no current flowing through the dummy pad DP. The dummy pad DP may be disposed between the ground pad GP and the first power pad PP1 and may be adjacent to the ground pad GP and the first power pad PP1.

A diameter of the dummy pad DP may be substantially equal to a diameter of one of pads, which are adjacent to each other in the first direction D1 or second direction D2. In the example shown in FIG. 3A, one of a diameter X1 of the ground pad GP and a diameter X2 of the first power pad PP1 may be substantially equal to a diameter X3 of the dummy pad DP.

A thickness of the dummy pad DP may be substantially equal to a thickness of one of pads, which are adjacent to each other in the first direction D1 or the second direction D2. In the example shown in FIG. 3A, one of a thickness T1 of the ground pad GP and a thickness T2 of the first power pad PPI may be substantially equal to a thickness T3 of the dummy pad DP.

A pitch between the dummy pad DP and one of pads, which are adjacent to each other in the first direction DI or second direction D2, may be substantially equal to a pitch between the pads. In the example shown in FIG. 2, a pitch P1 between adjacent ones of the first power pads PPI may be substantially equal to a pitch P2 between the first power pad PP1 and the dummy pad DP, which are adjacent to each other.

The second penetration electrodes 250 of the upper second semiconductor chip 200U may respectively overlap with the ground pad GP and the first power pad PP1 in the third direction D3 and may not overlap with the dummy pad DP in the third direction D3.

Referring to FIGS. 2 and 3B, the second power line PM2 and the ground line GM may be spaced apart from each other in the first direction D1, with the dummy line DM interposed therebetween. The second power line PM2 may be extended in the second direction D2. The second power line PM2 and the ground line GM may be applied with different voltages from each other. A voltage level of a voltage applied to the second power line PM2 may be higher than a voltage level of a voltage applied to the first power line PM1. For example, the second power line PM2 may be applied with a voltage of 1.8 V. Since the second power pad PP2 is in contact with the second power line PM2 and is not in contact with other interconnection lines (e.g., the first power line PM1, the signal line SM, the dummy line DM, and the ground line GM), the same voltage applied to the second power line PM2 may be applied to the second power pad PP2. The dummy pad DP may be interposed between the second power pad PP2 and the ground pad GP and may be adjacent to the second power pad PP2 and the ground pad GP. The second penetration electrodes 250 of the upper second semiconductor chip 200U may respectively overlap with the second power pad PP2 and the ground pad GP in the third direction D3 and may not overlap with the dummy pad DP in the third direction D3.

Referring to FIGS. 2 and 3C, the first power line PM1 and the second power line PM2 may be spaced apart from each other in the first direction D1, with the dummy line DM interposed therebetween. The dummy pad DP may be interposed between the first power pad PP1 and the second power pad PP2 and may be adjacent to the first power pad PP1 and the second power pad PP2. The second penetration electrodes 250 of the upper second semiconductor chip 200U may respectively overlap with the first power pad PP1 and the second power pad PP2 in the third direction D3 and may not overlap with the dummy pad DP in the third direction D3.

Referring to FIGS. 2 and 3D, the first power line PM1 and the signal line SM may be spaced apart from each other in the second direction D2, with the dummy line DM interposed therebetween. The first power line PM1 and the signal line SM may be applied with different voltages from each other. A voltage level of the voltage applied to the first power line PM1 may be higher than a voltage level of the voltage applied to the signal line SM. For example, the voltage applied to the signal line SM may be 0 V (low state). The voltage applied to the signal line SM may be higher than 0 V and may be lower than the voltage applied to the first power line PM1 (high state). Since the signal pad SP is in contact with the signal line SM and is not in contact with other interconnection lines (e.g., the first power line PM1, the second power line PM2, the dummy line DM, and the ground line GM), the same voltage as applied to the signal line SM may be applied to the signal pad SP. The dummy pad DP may be interposed between the first power pad PP1 and the signal pad SP and may be adjacent to the first power pad PP1 and the signal pad SP. The second penetration electrodes 250 of the upper second semiconductor chip 200U may respectively overlap with the first power pad PP1 and the signal pad SP in the third direction D3 and may not overlap with the dummy pad DP in the third direction D3.

Referring to FIGS. 2 and 3E, the second power line PM2 and the signal line SM may be spaced apart from each other in the second direction D2, with the dummy line DM interposed therebetween. The dummy pad DP may be interposed between the second power pad PP2 and the signal pad SP and may be adjacent to the second power pad PP2 and the signal pad SP. The second penetration electrodes 250 of the upper second semiconductor chip 200U may respectively overlap with the second power pad PP2 and the signal pad SP in the third direction D3 and may not overlap with the dummy pad DP in the third direction D3.

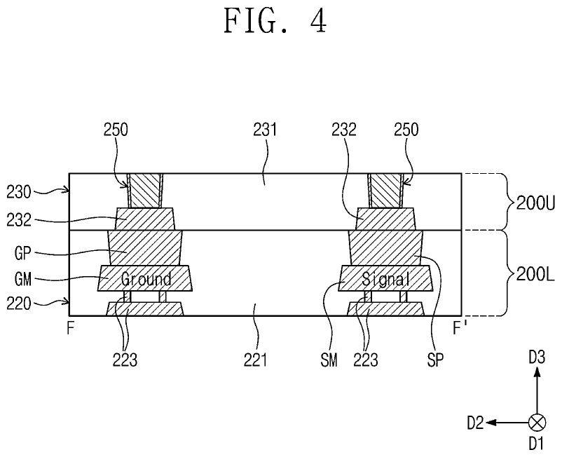

FIG. 4 is a sectional view schematically illustrating a bonding portion of second semiconductor chips corresponding to a section of a line F-F′ of FIG. 2.

Referring to FIGS. 2 and 4, even when the second upper bonding pads 222 of different kinds are disposed to be adjacent to each other, the dummy pad DP may be omitted if there is substantially no potential difference. For example, the ground line GM and the signal line SM may be disposed to be adjacent to each other in the second direction D2. In the case where the ground line GM and the signal line SM are applied with a voltage of 0 V, there may be no difference in electric potential therebetween. The ground pad GP and the signal pad SP may also be disposed to be adjacent to each other in the second direction D2.

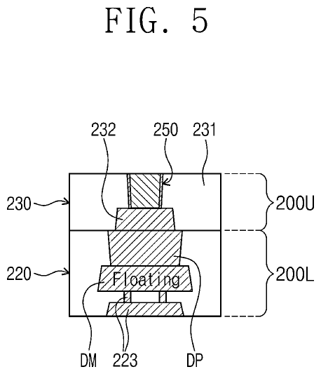

FIG. 5 is a sectional view schematically illustrating a bonding portion of second semiconductor chips according to an embodiment of the present disclosure.

Referring to FIGS. 2 and 5, the second penetration electrode 250 may be disposed on the second lower bonding pad 232, which is in contact with the dummy pad DP. For example, the dummy pad DP and the second penetration electrode 250 may overlap with each other in the third direction D3.

FIGS. 1 to 5 illustrate an example, in which the second semiconductor chips 200 are adjacent to each other in the third direction D3, but the dummy pad, which is disposed between and adjacent to pads with a potential difference, may also be applied to the first semiconductor chip 100 and the second semiconductor chip 200, which are adjacent to each other in the third direction D3. For example, the first semiconductor chip 100 may include a dummy pad, which is placed between and adjacent to pads having different electric potentials. Furthermore, even in a structure different from the afore-described high bandwidth memory (HBM) structure, a dummy pad may also be provided between and adjacent to pads, which are included in semiconductor chips forming a hybrid bonding structure and have different electric potentials.

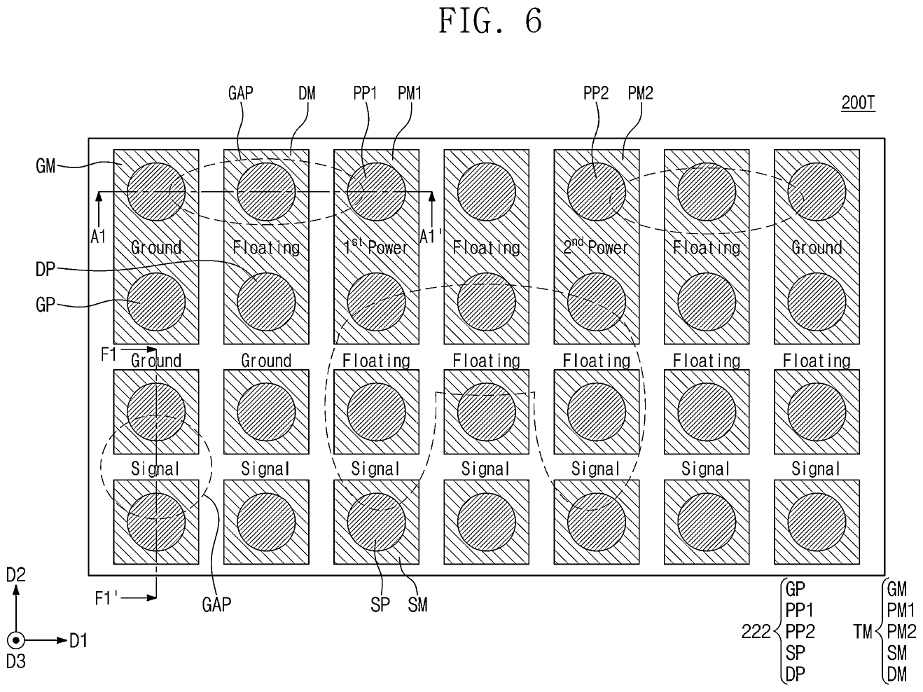

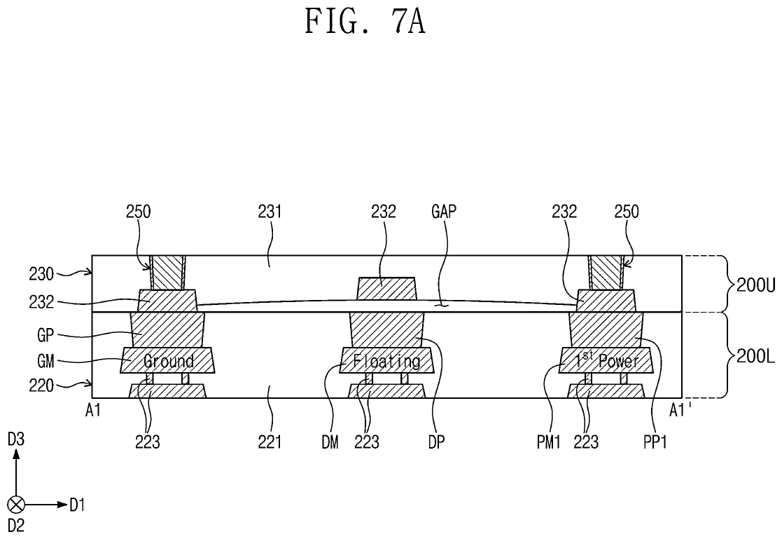

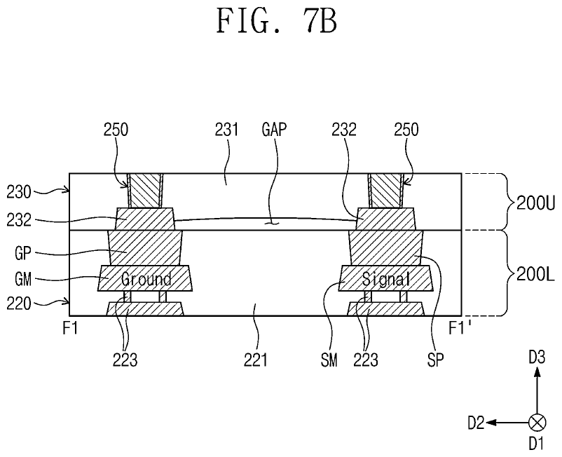

FIG. 6 is a plan view illustrating a bonding void on the top plan view of FIG. 2. FIG. 7A is a sectional view schematically illustrating a bonding portion of second semiconductor chips corresponding to a section of a line A1-A1′ of FIG. 6. FIG. 7B is a sectional view schematically illustrating a bonding portion of second semiconductor chips corresponding to a section of a line F1-F1′ of FIG. 6.

Referring to FIGS. 6 and 7A, a bonding void GAP may be formed between the second semiconductor chips 200 forming a hybrid bonding structure. For example, the bonding void GAP may be formed between the ground pad GP and the first power pad PP1. In an embodiment, the dummy pad DP may be disposed between the second upper bonding pads 222 (e.g., the ground pad GP and the first power pad PP1), which are applied with different voltages from each other. The dummy pad DP may be electrically isolated from other conductive elements to reduce a potential difference between the ground pad GP and the first power pad PP1. In this case, a conductive material may not be moved through the bonding void, even when the bonding void is formed therebetween. As a result, it may be possible to prevent a conductive bridge and a short circuit from being formed between adjacent ones of the pads, thereby improving the reliability of the semiconductor package.

The dummy pad DP may be disposed on the uppermost metal line TM, similar to the ground pad GP or the first power pad PP1 adjacent thereto. In addition, the dummy pad DP may have substantially the same diameter, thickness, and pitch as at least one of the second upper bonding pads 222. As a result, it may be possible to prevent a dishing phenomenon from occurring in a planarization process (e.g., chemical-mechanical polishing (CMP)), which is performed on the second upper interconnection layer 220 to form the second semiconductor chip 200. Furthermore, it may be possible to prevent thermal expansion in a specific region caused by an uneven pattern density.

Referring to FIGS. 6 and 7B, the dummy pad DP may be absent between the second upper bonding pads 222, which are adjacent to each other and are applied with the same voltage. In this case, the conductive bridge may not be formed, even when the bonding void GAP is formed.

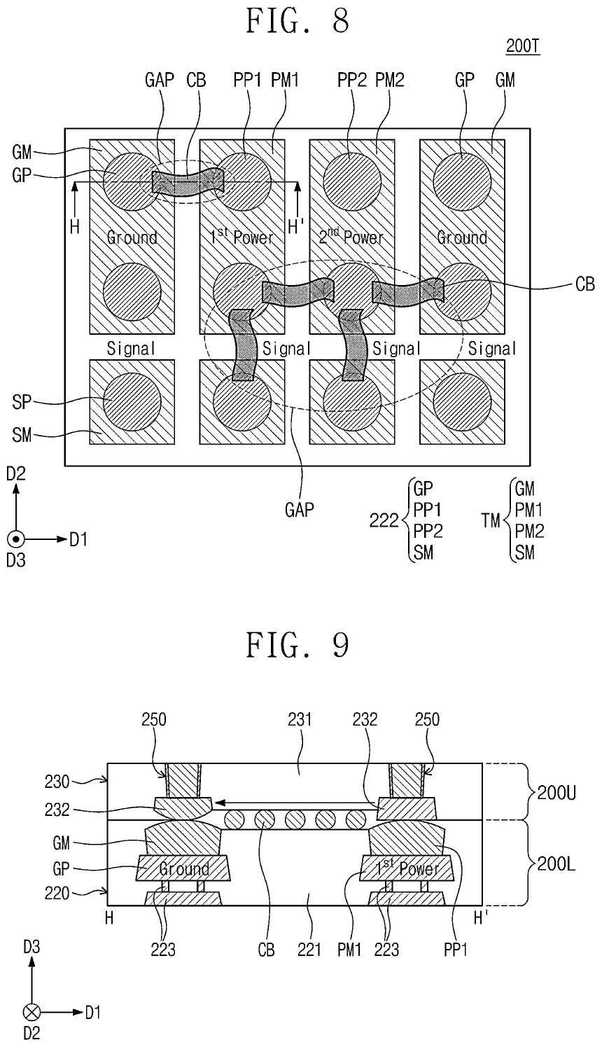

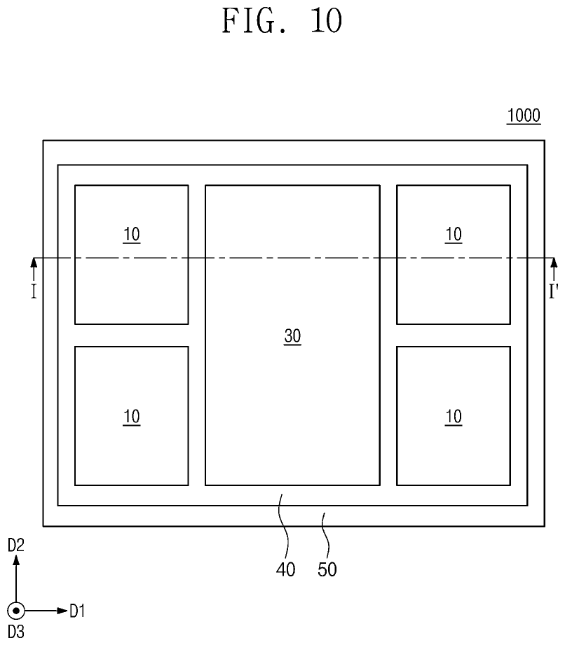

FIG. 8 is a plan view illustrating upper bonding pads, an uppermost metal line, and a bonding void, which are disposed on a top surface of a second semiconductor chip according to a comparative example. FIG. 9 is a sectional view schematically illustrating a bonding portion of second semiconductor chips corresponding to a section of a line H-H′ of FIG. 8. Referring to FIG. 8, the second upper bonding pads 222, which are applied with different voltages from each other, may be disposed in the first direction D1 and/or the second direction D2.

Referring to FIGS. 8 and 9, the ground pad GP and the first power pad PP1 may be disposed to be adjacent to each other in the first direction D1. For example, the bonding void GAP may be formed between the ground pad GP and the first power pad PP1. Since a conductive material is moved through the bonding void GAP by a potential difference between the ground pad GP and the first power pad PP1, a conductive bridge CB may be formed between the ground pad GP and the first power pad PP1. The conductive bridge CB may be formed of or include, for example, copper. The conductive bridge CB may result in an undesired connection (i.e., short circuit) between the ground pad GP and the first power pad PP1. FIG. 9 illustrates an example, in which the conductive bridge CB is formed between the ground pad GP and the first power pad PP1, but if any two adjacent pads have different electric potentials in a region with the bonding void GAP, the conductive bridge CB may also be formed between such pads, as shown in FIG. 8.

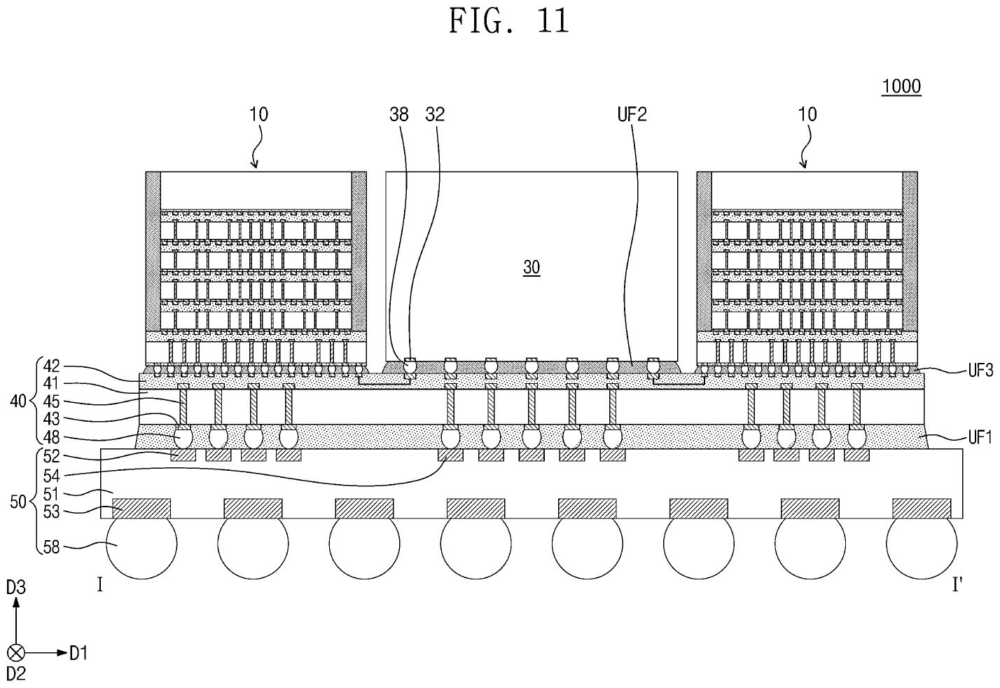

FIG. 10 is a plan view illustrating a semiconductor package according to an embodiment of the present disclosure. FIG. 11 is a schematic sectional view taken along a line I-I′ of FIG. 10. In order to reduce complexity in the drawings and to provide better understanding of example embodiments of the present disclosure, some elements in FIG. 11 may be omitted from FIG. 10. In the following description, substantially the same elements as any of the aforementioned elements will be referenced with the same numerals and repeated descriptions thereof may be omitted.

In an embodiment, a semiconductor package 1000 may include a package substrate 50, an interposer 40, a third semiconductor chip 30, a plurality of semiconductor packages 10 (e.g., chip stacks), a first under fill pattern UF1, a second under fill pattern UF2, and a third under fill pattern UF3. The semiconductor packages 10 (e.g., a chip stack) of FIGS. 10 and 11 may correspond to the semiconductor package 10 in the afore-described embodiments.

In an embodiment, the package substrate 50 may be a printed circuit board (PCB). The package substrate 50 may include lower metal pads 53, first upper metal pads 52, second upper metal pads 54, metal lines, and outer connection terminals 58. The first upper metal pads 52, the second upper metal pads 54 may be disposed in an upper portion of the package substrate 50, and the lower metal pads 53 may be disposed in a lower portion of the package substrate 50. The first upper metal pads 52 may be overlapped with the semiconductor package 10 in the third direction D3. The second upper metal pads 54 may be overlapped with the third semiconductor chip 30 in the third direction D3. The first upper metal pads 52 and the second upper metal pads 54 may be in contact with first connection terminals 48, respectively, which will be described below. The metal lines may connect the first upper metal pads 52 and the second upper metal pads 54 to the lower metal pads 53. The outer connection terminals 58 may be disposed on the lower metal pads 53, respectively. The outer connection terminals 58 may include a conductive material (e.g., a soldering material).

The interposer 40 may be disposed on the package substrate 50. The interposer 40 may include a third semiconductor substrate 41, third penetration electrodes 45, an interconnection layer 42, and the first connection terminals 48. The third semiconductor substrate 41 may be formed of or include a semiconductor material (e.g., silicon or germanium) and may be, for example, a silicon wafer. The interconnection layer 42 may be disposed on the third semiconductor substrate 41. The interconnection layer 42 may electrically connect the third semiconductor chip 30 to the semiconductor package 10. Each of the third penetration electrodes 45 may penetrate the third semiconductor substrate 41 and may be connected to the first connection terminal 48 through a pad 43.

A first under fill pattern UF1 may be interposed between the interposer 40 and the package substrate 50. The first under fill pattern UF1 may include, for example, an epoxy resin composition. The first under fill pattern UF1 may fill a space between the first connection terminals 48.

The third semiconductor chip 30 and the semiconductor packages 10 may be disposed on the interposer 40. In an embodiment, the third semiconductor chip 30 may be placed on a center portion of the interposer 40. The semiconductor packages 10 may be spaced apart from each other in the first direction D1, with the third semiconductor chip 30 interposed therebetween. The semiconductor packages 10 may include four chip stacks, two of which are arranged along a side surface of the third semiconductor chip 30 to be adjacent to each other, and the others of which are arranged along an opposite side surface of the third semiconductor chip 30 to be adjacent to each other, as shown in FIG. 10. On each side surface of the third semiconductor chip 30, the semiconductor packages 10 may be spaced apart from each other in the second direction D2.

In an embodiment, the semiconductor packages 10 may include six chip stacks, three of which are arranged along a side surface of the third semiconductor chip 30 to be adjacent to each other, and the others of which are arranged along an opposite side surface of the third semiconductor chip 30 to be adjacent to each other. However, embodiments of the present disclosure are not limited to these examples, and the arrangement of the semiconductor packages 10 may be variously changed.

The third semiconductor chip 30 may be a logic chip. For example, the third semiconductor chip 30 may be one from among a central processing Unit (CPU), a graphics processing unit (GPU), and an application specific integrated circuit (ASIC). The third semiconductor chip 30 may send or receive signals to or from the semiconductor packages 10. The third semiconductor chip 30 may include chip pads 32 provided in a lower portion thereof. Second connection terminals 38 may be disposed on the chip pads 32, respectively. The second connection terminals 38 may include a conductive material (e.g., a soldering material).

The second connection terminal 38 of the third semiconductor chip 30 and the connection terminal 180 of the semiconductor packages 10 may be in contact with pads, which are provided at a top surface of the interposer 40. A second under fill pattern UF2 may be disposed between the third semiconductor chip 30 and the interposer 40. The second under fill pattern UF2 may fill a space between the second connection terminals 38. A third under fill pattern UF3 may be interposed between each of the semiconductor packages 10 and the interposer 40. The third under fill pattern UF3 may fill a space between the connection terminals 180 (refer to FIG. 1). The second under fill pattern UF2 and third under fill pattern UF3 may include, for example, an epoxy resin composition.

According to an embodiment of the present disclosure, a dummy pad may be interposed between pads, which may have different electric potentials. The dummy pad may be in a floating state. In this case, a potential difference between the pads may be reduced by the dummy pad, and thus, even when a bonding void is formed between the pads, the dummy pad may prevent a conductive material from being moved through the bonding void. As a result, it may be possible to prevent a conductive bridge or a short circuit from being formed between the pads, thereby improving the reliability of the semiconductor package.

While non-limiting example embodiments of the present disclosure have been particularly shown and described, it will be understood by one of ordinary skill in the art that variations in form and detail may be made therein without departing from the spirit and scope of the present disclosure.

What is claimed is:

1. A semiconductor package, comprising:
a first semiconductor chip; and
a second semiconductor chip on the first semiconductor chip,
wherein an upper portion of the first semiconductor chip comprises upper bonding pads,
wherein a lower portion of the second semiconductor chip comprises lower bonding pads that are in direct contact with the upper bonding pads,
wherein the first semiconductor chip and the second semiconductor chip are connected to each other by the upper bonding pads and the lower bonding pads,
wherein the upper bonding pads comprise a first pad, a dummy pad, and a second pad, which are arranged in a first direction,
wherein the first pad is adjacent to the dummy pad and the dummy pad is adjacent to the second pad, such that the dummy pad is in between the first pad and the second pad, and
wherein the first pad and the second pad are configured to be applied with voltages of different levels from each other.

2. The semiconductor package of claim 1, wherein a difference between voltages applied to the first pad and the second pad is greater than or equal to 0.5 V.

3. The semiconductor package of claim 1, wherein the first pad is a power pad, and the second pad is a ground pad.

4. The semiconductor package of claim 1, wherein the first pad is a power pad, and the second pad is a signal pad.

5. The semiconductor package of claim 1, wherein the first pad is a first power pad,
wherein the second pad is a second power pad, and
wherein the second power pad is configured to be applied with a voltage that is higher than a voltage applied to the first power pad.

6. The semiconductor package of claim 1, wherein a diameter of the dummy pad is equal to a diameter of the first pad or a diameter of the second pad.

7. The semiconductor package of claim 1, wherein a thickness of the dummy pad is equal to a thickness of the first pad or a thickness of the second pad.

8. The semiconductor package of claim 1, wherein the first semiconductor chip further comprises:
a first uppermost metal line in contact with the first pad;
a second uppermost metal line in contact with the second pad; and
a third uppermost metal line in contact with the dummy pad,
wherein the first uppermost metal line and the second uppermost metal line are configured to be applied with different voltages from each other, and
wherein the third uppermost metal line is configured to be applied with a floating voltage.

9. The semiconductor package of claim 8, wherein the third uppermost metal line is not applied with any from among a signal voltage, a power voltage, and a ground voltage.

10. The semiconductor package of claim 8, wherein the first uppermost metal line, the second uppermost metal line, and the third uppermost metal line comprise aluminum, and
wherein the first pad, the second pad, and the dummy pad comprise copper.

11. The semiconductor package of claim 1, wherein the second semiconductor chip comprises penetration electrodes, and
wherein the penetration electrodes vertically overlap with the first pad and the second pad, respectively, but do not vertically overlap with the dummy pad.

12. The semiconductor package of claim 1, wherein the second semiconductor chip comprises a penetration electrode, and
wherein the penetration electrode vertically overlaps with the dummy pad.

13. The semiconductor package of claim 1, wherein the first semiconductor chip further comprises a first insulating layer covering a side surface of the first pad, a side surface of the dummy pad, and a side surface of the second pad,
wherein the second semiconductor chip further comprises a second insulating layer covering a side surface of each of the lower bonding pads, and
wherein the first insulating layer is in contact with the second insulating layer.

14. The semiconductor package of claim 13, further comprising a bonding void, which is interposed between the first insulating layer and the second insulating layer, in a region between the first pad and the second pad.

15. The semiconductor package of claim 1, wherein the upper bonding pads further comprise a third pad, an additional dummy pad, and a fourth pad,
wherein the first pad and the third pad are arranged in a second direction that is perpendicular to the first direction,
wherein the dummy pad and the additional dummy pad are arranged in the second direction, and
wherein the second pad and the fourth pad are arranged in the second direction and are configured to be applied with voltages of different levels from each other.

16. A semiconductor package, comprising:
a first semiconductor chip; and
a second semiconductor chip on the first semiconductor chip,
wherein an upper portion of the first semiconductor chip comprises upper bonding pads,
wherein a lower portion of the second semiconductor chip comprises lower bonding pads that are in direct contact with the upper bonding pads,
wherein the first semiconductor chip and the second semiconductor chip are connected to each other by the upper bonding pads and the lower bonding pads,
wherein the upper bonding pads comprise a first pad, a dummy pad, and a second pad, which are arranged in a first direction,
wherein the first pad is adjacent to the dummy pad and the dummy pad is adjacent to the second pad, such that the dummy pad is in between the first pad and the second pad, and
wherein the first pad is configured to be applied with a first power voltage,
wherein the second pad is configured to be applied with one from among a second power voltage, a ground voltage, and a signal voltage,
wherein a voltage level of the one from among the second power voltage, the ground voltage, and the signal voltage is greater than a voltage level of the first power voltage, and
wherein the dummy pad is configured to be applied with a floating voltage.

17. The semiconductor package of claim 16, wherein the voltage level of the first power voltage is different from the voltage level of the one from among the second power voltage, the ground voltage, and the signal voltage by a voltage difference of 0.5 V or higher.

18. A semiconductor package, comprising:
a package substrate;
an interposer on the package substrate;
a logic chip on the interposer; and
a plurality of chip stacks, which are spaced apart from each other with the logic chip interposed therebetween,
wherein each of the plurality of chip stacks comprises:
a first semiconductor chip; and
a second semiconductor chip on the first semiconductor chip,
wherein the first semiconductor chip comprises an upper insulating layer at an upper level of the first semiconductor chip, uppermost metal lines in the upper insulating layer, and upper bonding pads on the uppermost metal lines,
wherein the second semiconductor chip comprises a lower insulating layer at a lower level of the second semiconductor chip, and lower bonding pads in the lower insulating layer, the lower bonding pads being in direct contact with the upper bonding pads of the first semiconductor chip,
wherein the first semiconductor chip and the second semiconductor are bonded to each other through the upper bonding pads and the lower bonding pads,
wherein the upper bonding pads comprise a ground pad, a first power pad, a signal pad, and a first dummy pad,
wherein the first dummy pad is between one from among the signal pad and the ground pad and the first power pad, and
wherein the first dummy pad is disposed adjacent to the one from among the signal pad and the ground pad, and adjacent to the first power pad.

19. The semiconductor package of claim 18, wherein the upper bonding pads further comprise a second power pad and a second dummy pad,
wherein the second dummy pad is between and adjacent to the first power pad and the second power pad, and
a level of a voltage applied to the second power pad is higher than a level of a voltage applied to the first power pad.

20. The semiconductor package of claim 18, wherein the signal pad and the ground pad are adjacent to each other.
